(19) United States
(12) Patent Application Publication
(10) Pub. No.: US 2018/0047343 A1
(43) Pub. Date: Feb. 15, 2018

(54) PIXEL DRIVING CIRCUIT AND METHOD, PIXEL STRUCTURE AND DISPLAY DEVICE

(71) Applicant: BOE TECHNOLOGY GROUP CO., LTD., Beijing (CN)

(72) Inventors: Feng LIAO, Beijing (CN); Guangliang SHANG, Beijing (CN); Yuting ZHANG, Beijing (CN)

(73) Assignee: BOE TECHNOLOGY GROUP CO., LTD., Beijing (CN)

(21) Appl. No.: 15/523,849

(22) PCT Filed: Oct. 21, 2016
(86) PCT No.: PCT/CN2016/102950

§ 371 Date: May 2, 2017

(30) Foreign Application Priority Data
Jan. 11, 2016 (CN) 201610015162.1

(51) Int. Cl. G09G 3/3283; G05F 3/26; G09G 3/3266; H01L 51/50; G09G 3/38; G09G 3/325; G09G 3/3258

(52) U.S. Cl. CPC G09G 3/3283; G09G 3/325; G05F 3/262; G09G 3/3258; H01L 51/50; G09G 3/38; G09G 3/3266; G09G 2310/0262

(57) ABSTRACT

A pixel driving circuit and method, a pixel structure and display device. The pixel driving circuit includes: a driving transistor with a source electrode connected with a luminescent device; a capacitor structure with a first end connected with a gate electrode of the driving transistor; a first write control unit, configured to write a threshold voltage of the driving transistor into the first end of the capacitor structure at a write stage; a second write control unit, configured to write a data signal into a second end of the capacitor structure at the write stage; a power output control unit, configured to output a power supply signal to a drain electrode of the driving transistor at an emission stage; and a voltage follow control unit configured to control a voltage of the gate electrode to follow a change of a voltage of the source electrode of the driving transistor.

### TECHNICAL FIELD

Embodiments of the present disclosure relate to a pixel driving circuit and method, a pixel structure and a display device.

### BACKGROUND

In a traditional pixel structure of a luminescent device driven by current or voltage as shown in FIG. 1, a data signal is inputted into a control terminal of a driving transistor to charge a capacitor, and subsequently, a conduction degree of the driving transistor is controlled by utilization of the power stored in the capacitor, so as to control a current of the luminescent device.

In the pixel structure as shown in FIG. 1, the current I flowing across the luminescent device is: 0.5*μₙ*Cₒₓ*W/L*(V_{data}−Vₒₚₑᵣₐₜᵢₒₙ−Vₜₕ)², in which μₙ represents a carrier mobility ratio; Cₒₓ represents an equivalent capacitance of the driving transistor; W/L represents a width to length (w/l) ratio of the transistor; V_{data} represents a voltage of the data signal; Vₒₚₑᵣₐₜᵢₒₙ represents an operating voltage of the luminescent device; and V represents a threshold voltage of the driving transistor.

As threshold voltages Vₜₕ of different driving transistors and Vₒₚₑᵣₐₜᵢₒₙ of the luminescent device are different, when the current I flowing across the luminescent device is affected by Vₒₚₑᵣₐₜᵢₒₙ and Vₜₕ, a phenomenon of uneven display may occur to a display device, namely: different pixel units may have different brightness when driven by a same data signal.

### SUMMARY

Embodiments of the present disclosure provide a pixel driving circuit, used for driving a luminescent device in a pixel structure, comprising:

a driving transistor with a source electrode connected with the luminescent device;

a capacitor structure with a first end connected with a gate electrode of the driving transistor;

a first write control unit, configured to write a threshold voltage of the driving transistor into the first end of the capacitor structure at a write stage;

a second write control unit, configured to write a data signal into a second end of the capacitor structure at the write stage;

a power output control unit, configured to output a power supply signal to a drain electrode of the driving transistor at an emission stage; and

a voltage follow control unit configured to control, through the capacitor structure, a voltage of the gate electrode of the driving transistor to follow a change of a voltage of the source electrode of the driving transistor.

Embodiments of the disclosure provide a pixel structure, comprising a luminescent device and the foregoing pixel driving circuit for driving the luminescent device.

Embodiments of the disclosure provide a display device, comprising the foregoing pixel structure.

Embodiments of the disclosure provide a pixel driving method, used for driving the luminescent device in the foregoing pixel structure, comprising:

a voltage follow control step that includes controlling, through a capacitor structure in a pixel driving circuit, a voltage of a gate electrode of a driving transistor in the pixel driving circuit to follow a change of a voltage of a source electrode of the driving transistor at an emission stage.

### BRIEF DESCRIPTION OF THE DRAWINGS

In order to illustrate the technical solutions in the embodiments of the present disclosure or the existing arts more clearly, the drawings need to be used in the description of the embodiments or the existing arts will be briefly described in the following; it is obvious that the drawings described below are only related to some embodiments of the present disclosure, for one ordinary skilled person in the art, other drawings can be obtained according to these drawings without making other inventive work.

FIG. 1 illustrates a traditional pixel structure formed by a luminescent device driven by current or voltage;

FIG. 2 is a schematic diagram of a pixel structure with threshold voltage compensation;

FIG. 3 is a schematic structural view of a pixel driving circuit provided by an embodiment of the present disclosure;

FIG. 4 is a schematic structural view of a pixel driving circuit provided by an embodiment of the present disclosure, in which a voltage follow control unit is achieved by a TFT;

FIG. 5 is a schematic diagram illustrating writing a threshold voltage into a pixel driving circuit provided by an embodiment of the present disclosure;

FIG. 6 is a schematic structural view of a pixel driving circuit provided by an embodiment of the present disclosure, in which a second write control unit is achieved by a TFT;

FIG. 7 is a schematic structural view of a pixel driving circuit provided by an embodiment of the present disclosure, in which TFTs are multiplexed;

FIG. 8 is a timing diagram of the pixel driving circuit shown in FIG. 7; and

FIGS. 9 to 12 are schematic diagrams of equivalent circuits of the pixel driving circuit shown in FIG. 7 at different stages.

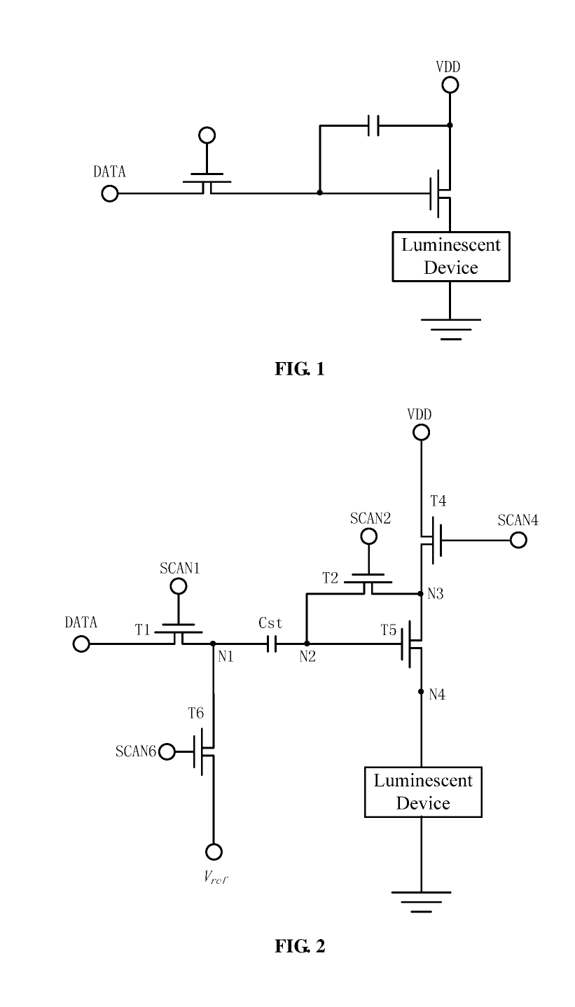

### DETAILED DESCRIPTION

Hereafter, the technical solutions of the embodiments of the present disclosure will be described in a clearly and fully understandable way in connection with the drawings related to the embodiments of the disclosure. It is obvious that the described embodiments are just a part but not all of the embodiments of the present disclosure. Based on embodiments of the present disclosure, all other embodiments obtained by those skilled in the art without making other inventive work should be within the scope of the present disclosure.

In order to avoid the phenomenon of uneven display, a solution as shown in FIG. 2 may be adopted for the Vₜₕ drift of the driving transistor. However, the solution as shown in FIG. 2 cannot ensure constancy of emission at an emission stage, as explained below.

A luminescent device driven by current or voltage such as an organic light-emitting diode (OLED) device or an electrochromic display (ECD) device has a property of a capacitor, and the capacitance thereof will be varied as the voltage changes.

That is to say, in a pixel structure with threshold voltage compensation, when changing from a write stage to the emission stage, a voltage at an N4 node as shown in FIG. 2 will be subjected to abrupt transition. But the pixel structure with threshold voltage compensation as shown in FIG. 2 does not have the ability of allowing the voltage of an N2 node to be varied along with the change of the voltage of the N4 node, causing Vgs of a driving transistor T5 to be varied at the emission stage. The variation of Vgs will result in change of the current flowing across the luminescent device, resulting in uneven brightness at the emission stage of the luminescent device.

A pixel driving circuit and method, a pixel structure and a display device, provided by embodiments of the present disclosure, can enhance the ability of allowing a gate electrode of a driving transistor to be varied along with change of a voltage of a source electrode of the driving transistor on the basis of threshold voltage compensation, and eliminate the influence of the capacitance characteristics of the luminescent device itself on display.

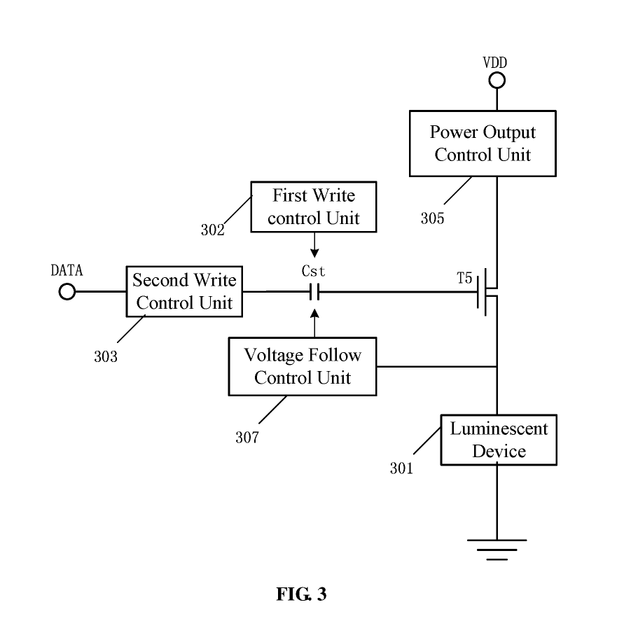

An embodiment of the present disclosure provides a pixel driving circuit, which is used for driving a luminescent device in a pixel structure. As illustrated in FIG. 3, the pixel driving circuit comprises:

a driving transistor T5, a source electrode of which is connected with a luminescent device 301;

a capacitor structure Cst, a first end of which is connected with a gate electrode of the driving transistor T5;

a first write control unit 302 configured to write a threshold voltage of the driving transistor T5 into the first end of the capacitor structure Cst at a write stage;

a second write control unit 303 configured to write a data signal into a second end of the capacitor structure Cst at the write stage;

a power output control unit 305 configured to output a power supply signal to a drain electrode of the driving transistor T5 at an emission stage; and

a voltage follow control unit 307, configured to control a voltage of the gate electrode of the driving transistor T5 to follow a change of a voltage of the source electrode of the driving transistor T5 through the capacitor structure Cst at the emission stage.

In general, when the pixel structure is changed from the write stage to the emission stage, due to the capacitance characteristics of the luminescent device, the voltage of the source electrode of the driving transistor will change. However, in the pixel driving circuit, the pixel structure and the display device, provided by the embodiments of the present disclosure, the transition of the voltage of the source electrode of the driving transistor is written into the gate electrode of the driving transistor by utilizing the ability of the capacitor structure in maintaining a voltage difference at its two ends, so that the voltage of the gate electrode of the driving transistor can be varied along with the change of the voltage of the source electrode of the driving transistor. Thus, Vgs of the driving transistor is kept unchanged, so that the influence of the capacitance characteristics of the luminescent device on display can be eliminated.

As the capacitance characteristics of the ECD are far greater than the capacitance characteristics of the OLED, the display effect can be greatly improved when the pixel driving circuit provided by the embodiments of the present disclosure is applied to the ECD.

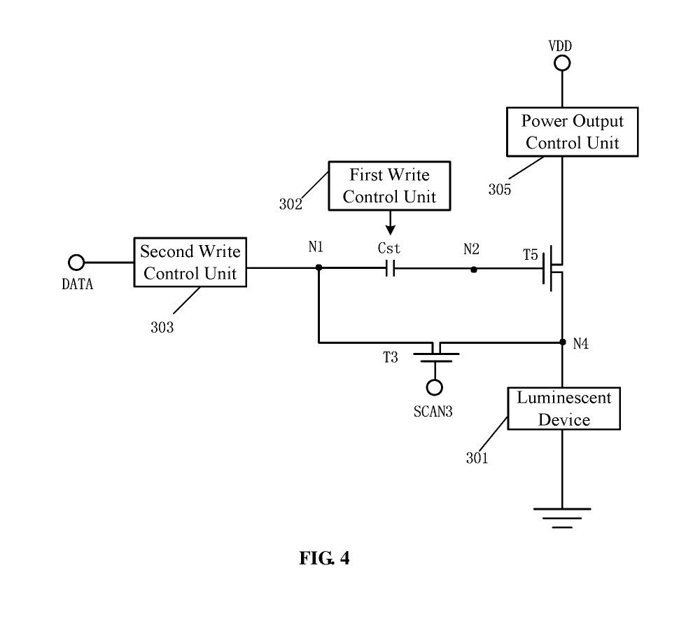

In an embodiment of the present disclosure, as shown in FIG. 4, the voltage follow control unit includes: a third thin film transistor (TFT) T3, configured to connect the source electrode of the driving transistor T5 to the second end of the capacitor structure Cst at the emission stage, so as to write the voltage of the source electrode of the driving transistor T5 into the gate electrode of the driving transistor T5.

As shown in FIG. 4, supposing that a voltage of an N1 node is V1 and a voltage of an N2 node is V2 before T3 is switched on, after T3 is switched on, the voltage of the N1 node will change to a voltage V3 of an N4 node (the voltage of the source electrode of the driving transistor T5 or the operating voltage of the luminescent device), namely a voltage variation of the voltage of the N1 node is: V3−V1.

Due to the ability of the capacitor structure Cst in maintaining the voltage difference at its two ends, when the voltage of the N1 node changes from V1 to V3, the voltage of the N2 node will change to V2+(V3−V1), and so, Vgs of the driving transistor=V2+(V3−V1)−V3=V2−V1.

That is to say, after the pixel structure is changed from the write stage to the emission stage, the gate-source voltage Vgs of the driving transistor T5 is irrelevant to the voltage of the source electrode of the driving transistor (or the operating voltage of the luminescent device), so the influence of the capacitance characteristics of the luminescent device on display can be eliminated.

In embodiments of the present disclosure, in order to realize threshold compensation, the threshold voltage of the driving transistor T5 may be written into the capacitor structure Cst, and the written threshold voltage is utilized to balance out the threshold voltage of the driving transistor at the emission stage, so as to maintain the voltage of the gate electrode of the driving transistor at the emission stage. Thus, the current flowing across the luminescent device is irrelevant to the threshold voltage Vth of the driving transistor.

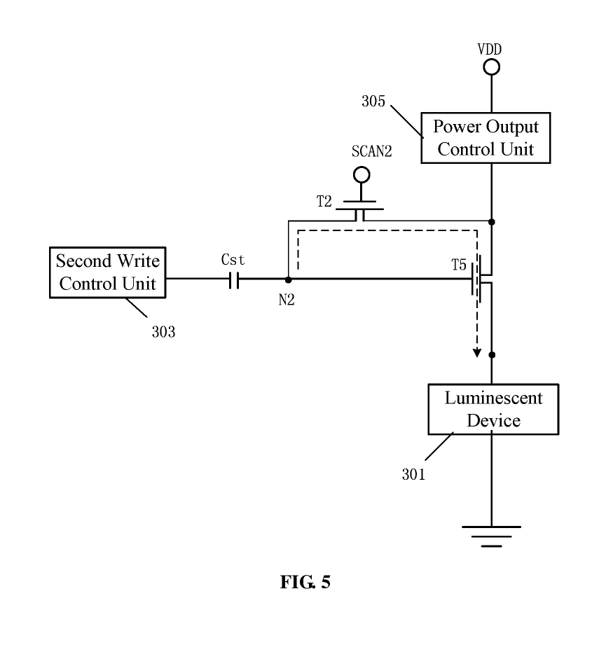

Implementations of the first write control unit are various. As shown in FIG. 5, the first write control unit may include: a second TFT T2, configured to connect the drain electrode of the driving transistor to the gate electrode of the driving transistor at the write stage, so as to write the threshold voltage of the driving transistor T5 into the first end of the capacitor structure Cst.

As shown in FIG. 5, at the write stage, when the second TFT T2 is switched on, the capacitor may discharge along a path shown by dashed lines in FIG. 5, and the discharge process may be ended until the voltage of the N2 node is changed into a sum of the threshold voltage of the driving transistor T5 and the threshold voltage of the luminescent device. After being stable, the voltage of the N2 node is the sum of the threshold voltage of the driving transistor T5 and the threshold voltage of the luminescent device, so that the write of the threshold voltage of the driving transistor T5 into the capacitor structure Cst can be achieved.

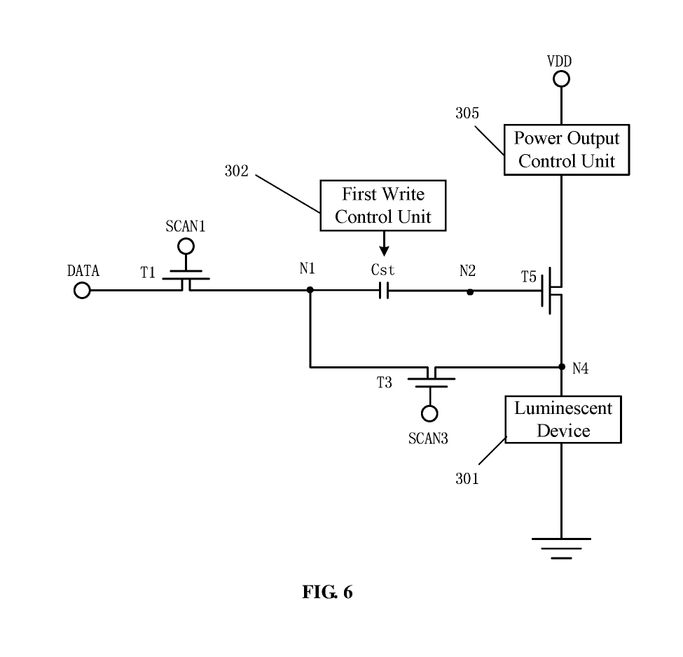

In embodiments of the present disclosure, the pixel driving circuit may need to utilize the data signal to control a conduction degree of the driving transistor and then control a current flowing across the luminescent device. An implementation of the second write control unit of the pixel driving circuit is, as shown in FIG. 6, achieved by a first TFT (T1). The first TFT (T1) is configured to connect an input terminal of the data signal to the second end of the capacitor structure at the write stage, so as to write the data signal into the second end of the capacitor structure Cst at the write stage.

After the data signal is written into the N1 node at the write stage, when the pixel structure is changed from the write stage to the emission stage, due to the ability of the capacitor structure Cst in maintaining the voltage difference, when the voltage of the N1 node changes, the data signal may be further written into the N2 node, so as to control the conduction degree of the driving transistor T5. No further description will be given here.

It should be understood that the capacitor structure may need to be charged (or may also be referred to as resetting) at first before the write of the data signal and the threshold voltage of the driving transistor. In embodiments of the present disclosure, a charge control structure may be separate from the first write control unit and the second write control unit. For instance, the charge structure may be achieved by using an approach of a reference signal Vref and a VDD signal as shown in FIG. 2.

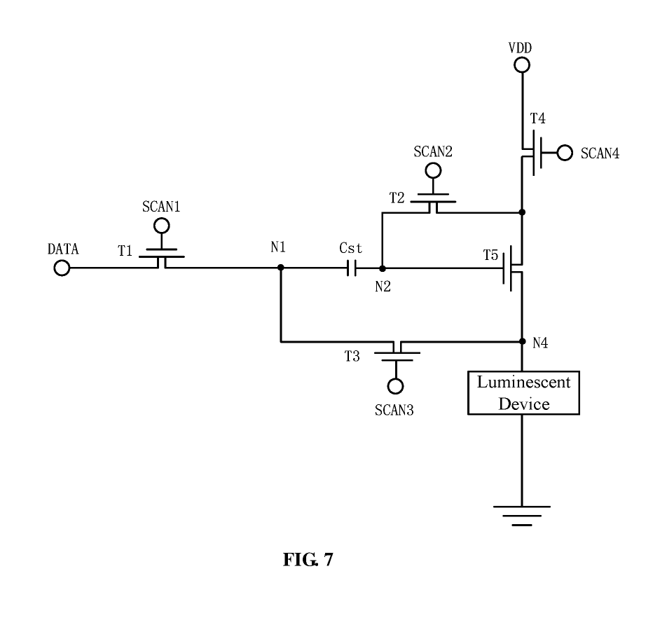

In order to reduce the number of the TFTs (for instance, omitting T6 in FIG. 2) and simplify the driving circuit, in an embodiment of the present disclosure, the previous transistors T1, T2 and T4 may be multiplexed to charge the capacitor structure. As shown in FIG. 7, in an embodiment of the present disclosure:

the power output control unit includes: a fourth TFT T4;

the first write control unit includes: a second TFT T2, configured to connect the drain electrode of the driving transistor to the gate electrode of the driving transistor at the write stage, so as to write the threshold voltage of the driving transistor T5 into the first end of the capacitor structure Cst;

the second write control unit includes: a first TFT T1, configured to connect the input terminal of the data signal to the second end of the capacitor structure at the write stage, so as to write the data signal into the second end of the capacitor structure Cst at the write stage; and

the first TFT T1, the second TFT T2 and the fourth TFT T4 are also switched on at a resetting stage, so as to charge the capacitor structure by using the power supply signal and the data signal.

As the first TFT T1, the second TFT T2 and the fourth TFT T4 are switched on at the resetting stage, the data signal may be applied to the N1 node and the VDD signal may be applied to the N2 node. Due to the voltage difference between the data signal and the VDD signal, the capacitor structure Cst may be charged to a certain degree at this stage.

Compared with the structure as shown in FIG. 2, the embodiment of the present disclosure removes a process of inputting an additional signal (the reference signal Vref), and then simplifies implementation of the circuit.

When the driving circuit provided by embodiments of the present disclosure is applied to the ECD, the capacitance of the above capacitor structure Cst is much larger than that of a capacitor structure in an OLED driving circuit. When a capacitor structure has large capacitance, the capacitor structure needs some time to reach a stable state after discharge. If the capacitor structure immediately enters the emission stage after discharge, the voltage of the N2 node may be varied in an initial time duration of the emission stage as the capacitor structure is instable. This variation may result in the change of Vgs of the driving transistor, causing the emission of light to be instable at the emission stage.

Therefore, in order to eliminate the influence of the capacitor structure on display at the emission stage, in an embodiment of the present disclosure:

the power output control unit includes: a fourth TFT T4;

the voltage follow control unit includes: a third TFT T3, configured to connect the source electrode of the driving transistor T5 to the second end of the capacitor structure Cst at the emission stage, so as to write the voltage of the source electrode of the driving transistor T5 into the gate electrode of the driving transistor T5;

the first write control unit includes: a second TFT T2, configured to connect the drain electrode of the driving transistor to the gate electrode of the driving transistor at the write stage, so as to write the threshold voltage of the driving transistor T5 into the first end of the capacitor structure Cst;

the second write control unit includes: a first TFT T1, configured to connect the input terminal of the data signal to the second end of the capacitor structure at the write stage, so as to write the data signal into the second end of the capacitor structure Cst at the write stage; and

the first TFT T1, the second TFT T2, the third TFT T3 and the fourth TFT T4 are also switched off at a buffer stage that is between the write stage and the emission stage.

Due to the setting of the buffer stage, the capacitor structure may have a time period to restore to the stable state after discharge, so that the influence of the variation of the capacitor structure on the voltage of the gate electrode of the driving transistor at the emission stage can be avoided, thereby further ensuring uniformity of brightness of the luminescent device at the emission stage.

Detailed description will be given below to a driving circuit provided by an embodiment of the present disclosure.

As illustrated in FIG. 7, a driving circuit provided by an embodiment of the present disclosure comprises:

a driving transistor T5, a source electrode of which is connected with a luminescent device;

a capacitor structure Cst, a first end of which is connected with a gate electrode of the driving transistor T5;

a first TFT T1, in which a first electrode of the first TFT T1 is connected with an input terminal DATA of a data signal, a second electrode of the first TFT T1 is connected with a second end of the capacitor structure Cst, and a gate electrode of the first TFT T1 is connected with an input terminal SCAN1 of a first control signal, where the first electrode may be a source electrode and the second electrode may be a drain electrode, or the first electrode is a drain electrode and the second electrode is a source electrode (for instance, the source electrode of the first TFT T1 is connected with the input terminal DATA of the data signal, and the drain electrode is connected with the second end of the capacitor structure Cst; or, the source electrode of the first TFT T1 is connected with the second end of the capacitor structure Cst, and the drain electrode is connected with the input terminal DATA of the data signal);

a second TFT T2, in which a first electrode of the second TFT T2 is connected with a drain electrode of the driving transistor T5, a second electrode of the second TFT T2 is connected with the gate electrode of the driving transistor T5, a gate electrode of the second TFT T2 is connected with an input terminal SCAN2 of a second control signal, where the first electrode may be a source electrode and the second electrode may be a drain electrode, or, the first electrode is a drain electrode and the second electrode is a source electrode (for instance, the source electrode of the second TFT T2 is connected with the drain electrode of the driving transistor T5, and the drain electrode of the second TFT T2 is connected with the gate electrode of the driving transistor T5; or, the source electrode of the second TFT T2 is connected with the gate electrode of the driving transistor T5, and the drain electrode of the second TFT T2 is connected with the drain electrode of the driving transistor T5);

a third TFT T3, in which a first electrode of the third TFT T3 is connected with the source electrode of the driving transistor T5, a second electrode of the third TFT T3 is connected with the second end of the capacitor structure Cst, and a gate electrode of the third TFT T3 is connected with an input terminal SCAN3 of a third control signal (for instance, a source electrode of the third TFT T3 is connected with the source electrode of the driving transistor T5, and a drain electrode of the third TFT T3 is connected with the second end of the capacitor structure; or, the source electrode of the third TFT T3 is connected with the second end of the capacitor structure Cst, and the drain electrode of the third TFT T3 is connected with the source electrode of the driving transistor T5); and

a fourth TFT T4, in which a first electrode of the fourth TFT T4 is connected with an input terminal VDD of a power supply signal, a second electrode of the fourth TFT T4 is connected with the drain electrode of the driving transistor T5, and a gate electrode of the fourth TFT T4 is connected with an input terminal SCAN4 of a fourth control signal, where the first electrode may be a source electrode and the second electrode may be a drain electrode, or, the first electrode is a drain electrode and the second electrode is a source electrode.

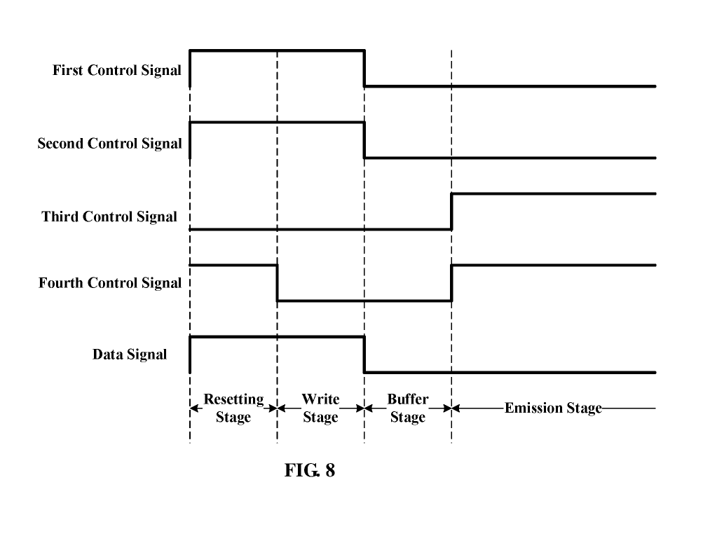

A timing diagram of the first, second, third and fourth control signals and the data signal is shown in FIG. 8.

Description will be given below to a working process of the driving circuit provided by an embodiment of the present disclosure with reference to FIGS. 7 and 8.

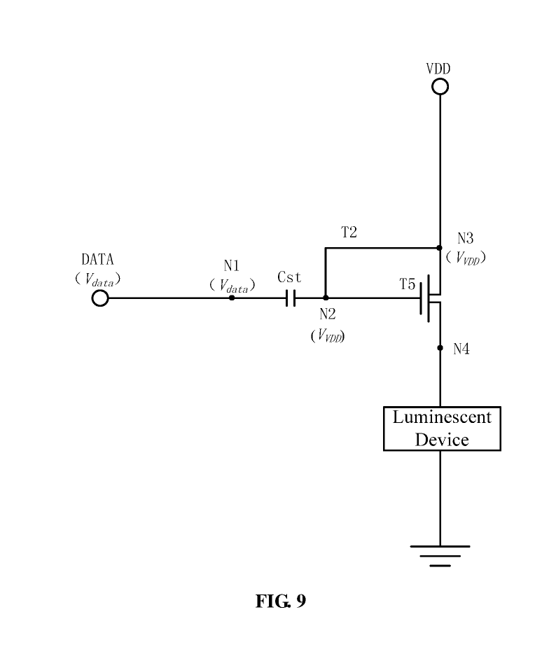

At a resetting stage, the first, second and fourth control signals are in a high voltage level and the third control signal is in a low voltage level. At this point, the TFTs T1, T2, T4 and T5 are switched on, and the TFT T3 is switched off. An equivalent circuit diagram of the pixel driving circuit is as shown in FIG. 9. At this point, the data signal is applied to the N1 node but the power supply signal is applied to the N2 node. The capacitor structure Cst is charged by using the voltage difference between the N1 node and the N2 node.

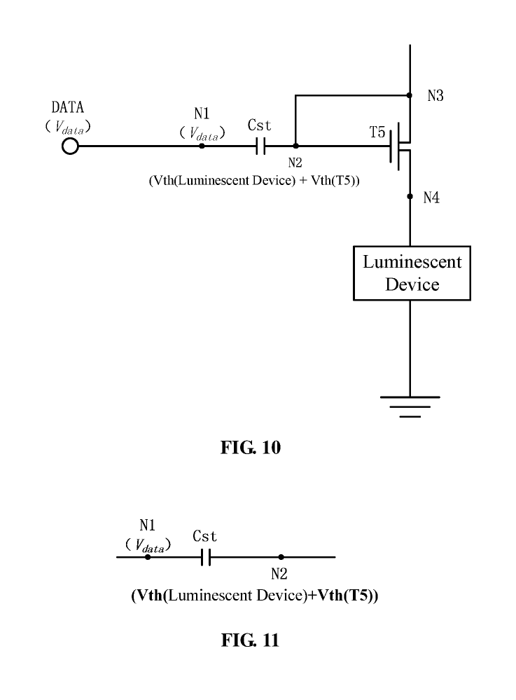

A write stage is entered after completion of charging and includes the writing of the data signal and the threshold voltage of the TFT T5. At this stage, the first and second control signals are in the high voltage level; the third and fourth control signals are in the low voltage level; the TFTs T1, T2 and T5 are switched on; and the TFTs T3 and T4 are switched off. An equivalent circuit diagram is as shown in FIG. 10.

At this point, the voltage of the N1 node is kept unchanged, but the voltage of the N2 node may be discharged to be a sum of the threshold voltage Vth(T5) of the driving transistor T5 and the threshold voltage Vth(luminescent device) of the luminescent device along a path passing through N2, N3, T5 and the luminescent device, so as to achieve the write of the data voltage and the threshold voltage Vth(T5) of the driving transistor T5.

A buffer stage is entered after the end of the write stage. All the control signals are in the low voltage level, and all the TFTs are switched off. An equivalent circuit diagram is as shown in FIG. 11. The capacitor structure enters a stable state after the end of the buffer stage.

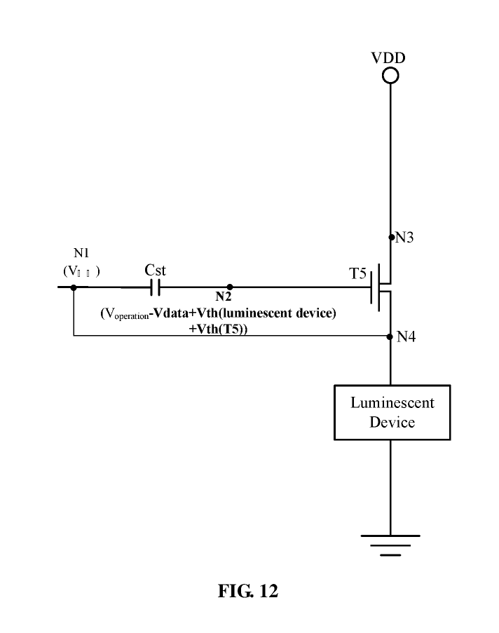

An emission stage is entered after the end of the buffer stage. At this stage, the first and second control signals are in the low voltage level; the third and fourth control signals are in the high voltage level; the TFTs T3, T4 and T5 are switched on; and the TFTs T1 and T2 are switched off. An equivalent circuit diagram is as shown in FIG. 12.

For, the voltage of the N1 node may change from Vdata to Voperation. Due to the coupling effect of Cst, in a case of a constant total amount of charges, the voltage of the N2 node may change from Vth(luminescent device)+Vth(T5) to:

Voperation−Vdata+Vth(luminescent device)+Vth(T5).

Therefore, Vgs of the driving transistor at the emission stage is the difference between the voltage of the N2 node and the voltage of the N4 node, namely:

Voperation−Vdata+Vth(luminescent device)+Vth(T5)−Voperation=Vth(luminescent device)+Vth(T5)−Vdata.

Thus, a current flowing across the luminescent device is:

0.5*μₙ*Cox*W/L*(Vgs−Vth(T5))².

That is, the current flowing across the luminescent device is:

0.5*μₙ*Cox*W/L*(Vth(luminescent device)−Vdata)².

It can be found that the current flowing across the luminescent device not only is irrelevant to the threshold voltage Vth(T5) of the driving transistor but also is irrelevant to the operating voltage Voperation of the luminescent device. Thus, influence of the capacitance characteristics of the luminescent device on display can be eliminated while achieving threshold compensation.

An embodiment of the present disclosure further provides a pixel structure, which comprises a luminescent device and further comprises any foregoing pixel driving circuit for driving the luminescent device.

An embodiment of the present disclosure further provides a display device, which comprises the foregoing pixel structure.

The transistors adopted in the embodiments of the present disclosure may be TFTs, field effect transistors (FETs), or similar diodes with other characteristics. As the source electrodes and the drain electrodes of the adopted transistors are symmetrical, the source electrodes and the drain electrodes of the transistors have no difference.

Description has been given in the above embodiments by taking an N-type transistor as an example. When a signal with a high voltage level is inputted into a gate electrode, a source electrode and a drain electrode are connected to each other. A P-type transistor is different. When a signal with a low voltage level is inputted into a gate electrode, a source electrode and a drain electrode are connected to each other. It is obvious that implementation of the above embodiments with the P-type transistors may be easily conceived by those skilled in the art without creative efforts, and hence shall also fall within the scope of protection of the embodiments of the present disclosure.

An embodiment of the present disclosure further provides a pixel driving method, which is used for driving a luminescent device in a pixel structure. The pixel driving method comprises:

a voltage follow control step, namely controlling a voltage of the gate electrode of the driving transistor in the pixel driving circuit to follow a change of the voltage of the source electrode of the driving transistor through the capacitor structure in the pixel driving circuit at the emission stage.

In the pixel driving method, the voltage follow control step includes: connecting the source electrode of the driving transistor to the second end of the capacitor structure at the emission stage.

The pixel driving method further comprises: disconnecting the capacitor structure from an external circuit between the write stage and the emission stage, so that the capacitor structure can have a period of time to restore to the stable stage after discharge. Thus, the influence of the variation of the capacitor structure on the voltage of the gate electrode of the driving transistor at the emission stage can be avoided, and it further ensures the brightness consistency of the luminescent device at the emission stage.

In the present disclosure, terms such as “first”, “second” and the like used in the present disclosure do not indicate any sequence, quantity or significance but only for distinguishing different constituent parts. Also, the terms such as “a,” “an,” or “the” etc., are not intended to limit the amount, but indicate the existence of at lease one. The terms “comprises,” “comprising,” “includes,” “including,” etc., are intended to specify that the elements or the objects stated before these terms encompass the elements or the objects and equivalents thereof listed after these terms, but do not preclude the other elements or objects.

Obviously, those skilled in the art may modify the disclosure in various ways without breaking away from the spirits and scope of the disclosure. And so, if these changes and variations of the disclosure also fall within the scope of the claims or their equivalent technologies, the disclosure intends to include these changes and variations.

What are described above is related to the illustrative embodiments of the disclosure only and not limitative to the scope of the disclosure; any changes or replacements easily for those technical personnel who are familiar with this technology in the field to envisage in the scopes of the disclosure, should be in the scope of protection of the present disclosure. Therefore, the scopes of the disclosure are defined by the accompanying claims.

The present application claims the priority of the Chinese Patent Application No. 201610015162.1 filed on Jan. 11, 2016, which is incorporated herein by reference in its entirety as part of the disclosure of the present application.

1. A pixel driving circuit, used for driving a luminescent device in a pixel structure, comprising:
a driving transistor with a source electrode connected with the luminescent device;
a capacitor structure with a first end connected with a gate electrode of the driving transistor;
a first write control unit, configured to write a threshold voltage of the driving transistor into the first end of the capacitor structure at a write stage;
a second write control unit, configured to write a data signal into a second end of the capacitor structure at the write stage;
a power output control unit, configured to output a power supply signal to a drain electrode of the driving transistor at an emission stage; and
a voltage follow control unit configured to control, through the capacitor structure, a voltage of the gate electrode of the driving transistor to follow a change of a voltage of the source electrode of the driving transistor.

2. The pixel driving circuit according to claim 1, wherein
the capacitor structure includes the first end and the second end; and
the second write control unit includes: a first thin film transistor (TFT), configured to connect an input terminal of the data signal to the second end of the capacitor structure at the write stage, so as to write the data signal into the second end of the capacitor structure at the write stage.

3. The pixel driving circuit according to claim 1, wherein the first write control unit includes: a second TFT, configured to connect a drain electrode of the driving transistor to the gate electrode of the driving transistor at the write stage, so as to write a threshold voltage of the driving transistor into the first end of the capacitor structure.

4. The pixel driving circuit according to claim 1, wherein the voltage follow control unit includes: a third TFT, configured to connect the source electrode of the driving transistor to the second end of the capacitor structure at the emission stage.

5. The pixel driving circuit according to claim 1, wherein
the power output control unit includes: a fourth TFT;
the first write control unit includes: a second TFT, configured to connect a drain electrode of the driving transistor to the gate electrode of the driving transistor at the write stage, so as to write a threshold voltage of the driving transistor into the first end of the capacitor structure;
the second write control unit includes: a first TFT, configured to connect an input terminal of the data signal to the second end of the capacitor structure at the write stage, so as to write the data signal into the second end of the capacitor structure at the write stage; and
the first TFT, the second TFT and the fourth TFT are also switched on at a resetting stage, so as to charge the capacitor structure by using the power supply signal and the data signal.

6. The pixel driving circuit according to claim 4, wherein
the power output control unit includes: a fourth TFT;
the first write control unit includes: a second TFT, configured to connect the drain electrode of the driving transistor to the gate electrode of the driving transistor at the write stage, so as to write the threshold voltage of the driving transistor into the first end of the capacitor structure;
the second write control unit includes: a first TFT, configured to connect an input terminal of the data signal to the second end of the capacitor structure at the write stage, so as to write the data signal into the second end of the capacitor structure at the write stage; and
the first TFT, the second TFT, the third TFT and the fourth TFT are also switched off at a buffer stage that is between the write stage and the emission stage.

7. The pixel driving circuit according to claim 1, wherein the luminescent device is an electrochromic display (ECD) device.

8. A pixel structure, comprising a luminescent device and the pixel driving circuit for driving the luminescent device according to claim 1.

9. A display device, comprising the pixel structure according to claim 8.

10. A pixel driving method, used for driving the luminescent device in the pixel structure according to claim 8, comprising:
a voltage follow control step that includes controlling, through a capacitor structure in a pixel driving circuit, a voltage of a gate electrode of a driving transistor in the pixel driving circuit to follow a change of a voltage of a source electrode of the driving transistor at an emission stage.

11. The pixel driving method according to claim 10, wherein the voltage follow control step includes: connecting the source electrode of the driving transistor to a second end of the capacitor structure at the emission stage.

12. The pixel driving method according to claim 11, further comprising:
disconnecting the capacitor structure from an external circuit between a write stage and the emission stage.

13. The pixel driving circuit according to claim 2, wherein the first write control unit includes: a second TFT, configured to connect a drain electrode of the driving transistor to the gate electrode of the driving transistor at the write stage, so as to write a threshold voltage of the driving transistor into the first end of the capacitor structure.

14. The pixel driving circuit according to claim 2, wherein the voltage follow control unit includes: a third TFT, configured to connect the source electrode of the driving transistor to the second end of the capacitor structure at the emission stage.

15. The pixel driving circuit according to claim 2, wherein
the power output control unit includes: a fourth TFT;
the first write control unit includes: a second TFT, configured to connect a drain electrode of the driving transistor to the gate electrode of the driving transistor at the write stage, so as to write a threshold voltage of the driving transistor into the first end of the capacitor structure;
the second write control unit includes: a first TFT, configured to connect an input terminal of the data signal to the second end of the capacitor structure at the write stage, so as to write the data signal into the second end of the capacitor structure at the write stage; and
the first TFT, the second TFT and the fourth TFT are also switched on at a resetting stage, so as to charge the capacitor structure by using the power supply signal and the data signal.

16. The pixel driving circuit according to claim 2, wherein the luminescent device is an electrochromic display (ECD) device.
